(19) United States
(12) Patent Application Publication
(10) Pub. No.: US 2025/0357081 A1
(43) Pub. Date: Nov. 20, 2025

(54) METHOD FOR FABRICATING NANOPATTERNED SUBSTRATES

(71) Applicant: THE PROVOST, FELLOWS, SCHOLARS AND OTHER MEMBERS OF THE BOARD OF TRINITY COLLEGE DUBLIN, Dublin (IE)

(72) Inventor: Parvaneh MOKARIAN, Dublin (IE)

(21) Appl. No.: 18/872,506

(22) PCT Filed: Jun. 6, 2023
(86) PCT No.: PCT/EP2023/065155

§ 371 Date: Dec. 6, 2024

(30) Foreign Application Priority Data
Jun. 6, 2022 (GB) 2208279.6

(51) Int. Cl. H01J 37/32; G02B 1/118

(52) U.S. Cl. CPC H01J 37/32174; G02B 1/118; H01J 37/321; H01J 37/32449; H01J 2237/3341; H01J 2237/3345; H01J 2237/3346

(57) ABSTRACT

The present invention relates to a method for producing low reflectivity substrates. Using block copolymer patterning and inductively coupled plasma etching, near-periodic dense nanopatterned structures are formed on one or more surfaces of substrates comprising of material such as glass, sapphire, silicon, silicon carbide, gallium nitride etc. The nanopatterned structures create a gradual change of refractive index thus reducing reflection compared to that of an un-patterned substrate. The nanopatterned structures reduces reflectivity to less than 0.5% for a double side patterned substrate almost an order of magnitude smaller than flat glass with a bandwidth of ˜300 nm. For samples patterned on both surfaces, total transmission greater than 99.5% was demonstrated. This was achieved by introducing and optimising an oxygen plasma step before etch, and optimising values of etch parameters such as reactive ion etching power, inductively coupled plasma power, and etch gas molar flow rate and composition.

### FIELD

The present disclosure relates to a method for fabricating nanopatterned substrates.

### BACKGROUND

Light is reflected at the interface between two media due to the abrupt change in speed of light as it passes from one media to the other. Since the speed of light in a medium is defined by the refractive index of the material in which it is travelling, optical reflections can equivalently be described as arising from abrupt changes in the refractive index of the media through which light is travelling.

Subwavelength texturing or nanopatterning structures on a substrate media is a method known in the art for mitigating undesirable optical reflections. Texturing reduces the abruptness of the refractive index discontinuity experienced by light and thereby reduces optical reflectivity. Nanostructures are features which can form antireflection structures on the substrate media. They are generally fabricated by electron beam lithography or by dry etching. Electron beam lithography is very slow and expensive which makes it impractical for industrial scale production. Further, etching of nanostructures in glass (including fused silica, BK7, gorilla glass, etc) and sapphire is difficult due to lack of crystallinity in glass, and impurities, chemical robustness, and hardness in sapphire. Etching nanoscale features also requires high selectivity between the mask and the substrate. Conventional hard masks for plasma etching are lithographically patterned at the microscale with tens or hundreds of microns thick metal etch masks. However, conventional lithography techniques are not suitable for nanopatterning large or curved surfaces. The challenge is to achieve optimal etch conditions in various glasses and sapphire to be able to etch nanopillars into them before the mask is depleted. Another issue is the well-known phenomenon of aspect ratio dependent etching (ARDE) due to which, the etch rate is decreased as the aspect ratio increases. This is due to the lower rate of diffusion of etchant species into the substrate, and the by-products out of the base of the nanostructures, as the etch proceeds. This phenomenon is a major issue for etching materials that are naturally difficult to etch and to create structures with high aspect ratio.

Laser interference lithography is another method known in the art that can be used to create microstructures on optical substrates. This method is fast, easy to fine tune, and fabricates high aspect ratio structures. It, however, needs special equipment and an additional chemical etch step to transfer the pattern.

Another known method in the art for reducing reflection in photonic or optical substrates, is coating the surface with a thin film or multiple thin films which produces destructive interference of the light reflected from each interface of the films. Thin-film antireflective coatings are typically limited in their wavelength and angle range (and the minimum of reflection also shifts as the incident angle is varied). The ideal antireflective coating for any surface is one which gives a gradual change from the external refractive index to the refractive index of the surface (known as GRIN—gradient refractive index). This is often attempted by combining multiple layers of different materials/structures to produce a GRIN effect. The difficulty of this method is producing structures with size and period less than a wavelength and that are robust, over large areas. Another pitfall is that large and/or widely spaced structures scatter light in all directions and thus cause haze and glare.

The use of optically transparent multi-layer metal coatings/dielectric coatings for anti-reflectance is known in the art. This method, however, leads to a purple cast at oblique angles, is limited to a narrow wavelength range, and is vulnerable to scratch and rub erosion.

Yet another method known in the art for mitigating optical reflection, is block copolymer nanopatterning such as the method described in PCT/EP2017/050736. This is suitable for creating subwavelength structures on large surfaces and curved objects. However, the drawback of this process is imperfection in the mask in terms of uniformity, coverage of the substrates and variation in feature size and periodicity. These issues are particularly more prevalent as the molecular weight of the polymer systems increases beyond five hundred (500) kg/mol. The lack of uniformity makes the optimization of the etch process extremely challenging. The method described in said patent application is also not proven to be omni-phobic.

International patent application—PCT/EP2008/002304 discloses a method for fabricating an antireflective surface on an optical element by coating micellar polymer units. This method, despite being low cost, needs an additional nanocluster enlargement step to create anti-reflectance. There is no confirmatory evidence of the efficacy of this method.

European patent publication EP 2306527 discloses a light emitting diode with a finely roughened structure. This method, even though it is low cost, uses harsh chemicals, and the processing time is ten to twelve hours at temperatures above 210 degrees celsius.

WO 2015/053828 discloses technologies effective for etching nanostructures in a substrate. The methods may comprise depositing a patterned block copolymer on the substrate, and applying a precursor to the patterned block copolymer to generate an infiltrated block copolymer, applying a removal agent to the infiltrated block copolymer to generate a patterned material. US 2012/0268823 relates to conical structures on substrate surfaces, in particular optical elements, to methods for the production thereof and to the use thereof, in particular in optical devices, solar cells and sensors. WO 2017/121888 provides a solution based process based on high molecular weight block copolymer (BCP) nanolithography for fabrication of periodic structures on large areas of optical surfaces. WO 2012/048870 relates to an improved process for producing highly ordered nanopillar or nanohole structures, in particular on large areas, which can be used as masters in NIL, hot embossing or injection moulding processes. JP 2013137446 provides an antireflection film excellent in shape followability, a mould for manufacturing the antireflection film, and a method of manufacturing the same.

However, introducing surface structures on substrates using methods known in the art can also lead to undesired light scattering causing reduced visibility (similar to streaks on a car windscreen when the sun is low in the sky). Light scattering occurs when there is a discontinuity in refractive index; thus, smooth transitions (i.e., smooth, densely packed, and small surface structures) are needed to achieve anti-glare properties in optical/photonic devices.

There is therefore an unfulfilled and unresolved need in the art for a low-cost method for fabricating a dense array of sub-wavelength nanopatterned structures on large and curved substrates which enables near total optical transmission and anti-glare properties, and this forms the primary objective of the present invention.

### SUMMARY

According to the present invention, there is provided as set out in the appended claims, a method for fabricating subwavelength nanopatterned structures on one or more surfaces of a substrate, through an optimized plasma etching process.

The method comprises the steps of depositing a block copolymer material on the one or more surfaces of the substrate, phase separating the block copolymer material, incorporating metal oxide particles in the block copolymer material, creating a metal oxide etch mask by using an oxygen plasma process, fabricating a dense array of nanopatterned structures on the one or more surfaces by a plasma etching process for a pre-determined time duration and controlling the dimensions of the nanopatterned structures by optimizing a plurality of etching process parameters.

In another aspect of the present invention, there is provided a method for fabricating subwavelength antireflection/anti-glare/anti-scattering/anti-haze nanopatterned structures on one or more surfaces of a substrate. The method includes the steps of depositing a block copolymer material on the one or more surfaces of the substrate, via spin coating or doctor blade or other coating technique, incorporating metal oxide particles in the block copolymer material, removing a matrix polymer by UV ozone, performing a masking process that includes creating a metal oxide etch mask by using an oxygen plasma process, to form oxidised metal dots on the FS surface, performing an etching process that includes fabricating a dense array of nanopatterned structures on the one or more surfaces by an induced coupled plasma-reactive ion etching (ICP-RIE) process for a pre-determined time duration, and controlling the dimensions of the nanopatterned structures by optimizing a plurality of masking and etching process parameters, wherein the optimized masking and etching process parameters comprises selective reactive ion etching power, inductively coupled plasma power, and etch gas composition and molar flow rate, and wherein the height of the nanopatterned structures is in the range two hundred to six hundred and fifty nanometers, and the aspect ratio of the nanopatterned structures is in the range three to five.

In one embodiment of the present invention, the step of incorporating metal oxide particles in the block copolymer material comprises infiltrating metal onto one of the polymers using a nickel metal, up to a concentration of approximately 2% or less.

The tailored oxygen plasma process provides optimal depth for oxidised nano-domain features on the mask for curating tall nanopillars, essential to achieve the desired antireflection functionality in broadband wavelengths of light. The oxygen plasma process further removes any polymer residue from the substrate, thus exposing a clean SiO2 surface for the etching process. Also, the oxygen plasma process removes the matrix polymer, thus forming a hard mask of nickel oxide dots on the FS surface, without effecting the metalised etch mask.

In an embodiment of the present invention, the reactive ion etching power is in the range twenty-five to eighty watts, the inductively coupled plasma power in the range fifty to two hundred watts, and a feed gas comprises oxygen used at the molar flow rate forty to eighty sccm for the masking process.

The optimized oxygen plasma process for creating the etch mask comprises reactive ion etching power in the range forty watts to seventy-five watts, inductively coupled plasma power in the range one hundred watts to three hundred watts, oxygen molar flow rate in the range fifty-five to sixty-five standard cubic centimetres per minute (sccm) and pressure in the range twenty-eight to thirty-two mTorr.

The reactive ion etching power in the range twenty-five watts to fifty-five watts, inductively coupled plasma power in the range five hundred watts to one thousand watts, oxygen molar flow rate in the range nine to eleven standard cubic centimetres per minute (sccm), tri-fluoro methane molar flow rate in the range twenty-nine to thirty-one sccm and pressure in the range fourteen to sixteen mTorr for the etching process. Ratio changes and pressure can also be used as selected parameters.

The height of the nanopatterned structures is in the range two hundred (200) to six hundred and fifty (650) nanometres, and the coverage of the nanopatterned structures is very uniform across the substrate. The aspect ratio of the nanopatterned structures is in the range three (3) to five (5).

In one embodiment of the present invention, the fabricated nanopatterned structures comprises a dense array of pillar or wire like structures.

In one embodiment of the present invention, the fabricated nanopatterned structures comprise a dense array of substantially conical shaped structures.

In one embodiment of the present invention, the predetermined plasma time duration for mask creation is in the range one minute to five minutes or longer for surfaces with larger areas. It will be appreciated for larger surface areas, for example large wafers, the time duration can be more than five minutes.

In one embodiment of the present invention, the predetermined etch time duration is in the range twenty minutes to sixty minutes or longer for surfaces with larger areas. It will be appreciated for larger surface areas, for example large wafers, the time duration can be more than sixty minutes.

The optimization of the etch process enables achievement of broadband anti-reflectivity and anti-glare in large and curved surfaces. Optical modelling was performed in order to guide the etch process and to determine the dimensions of the nanopatterned structures to be targeted in order to achieve anti-glare and antireflective functionalities. The morphology of the substrate is altered from flat to a dense array of nanopatterned structures which in turn creates a gradual change in the refractive index from the substrate to air thereby leading to enhanced optical performance.

In one embodiment of the present invention, the plasma etching process consists of an anisotropic plasma etching process.

In one embodiment of the present invention, the etch gas comprises oxygen at flow rate 10 sccm.

In one embodiment of the present invention, the one or more surfaces of the substrate comprises the top surface and the bottom surface of the substrate, wherein the top surface is disposed opposite to the bottom surface. By nanopatterning both sides of the substrate, optical transmission of greater than 99.5% was achieved which equates to less than 0.5% reflection. The present invention minimizes glare by densely packing the nanopatterned structures on the substrate, which can be tapered, thereby preventing surface scattering due to the nanopatterned structures. The present invention hence achieves antireflective and anti-glare properties at the same time.

In one embodiment of the present invention, the substrate comprises at least one of glass, plastic, semiconductor, sapphire, silicon, silicon carbide, or gallium nitride. In one embodiment of the present invention, the diameter of the substrate is up to six inches or more.

In one embodiment of the present invention, the substrate is a curved substrate.

In a preferred embodiment of the present invention, an optical device with a dense array of subwavelength nanopatterned structures is provided. The nanopatterned structures and the substrate comprises of the same material wherein there is no interface layer or boundary between the nanopatterned structures and the substrate. The optical device has an optical transmission greater than 99.5%.

In another preferred embodiment of the present invention, a photonic device with a dense array of subwavelength nanopatterned structures is provided. The nanopatterned structures and the substrate comprises of the same material, and wherein there is no interface layer or boundary between the nanopatterned structures and the substrate. The photonic device has an optical transmission greater than 99.5%.

The present invention hence enables plasma etching of subwavelength nanopatterned structures over a large surface area on materials such as glass and sapphire which are intrinsically difficult to etch. In comparison to methods known in the art, the nanopatterned structures fabricated by the present invention are a much denser array at similar or higher heights. The higher aspect ratio leads to enhanced transmittance over broad range of spectral wavelengths and angles of incidence.

The present invention allows optimizing masks and is robust to be used for a variety of different sized nanostructures and for a wide range of substrates such as BK7 glass, fused silica, and gorilla glass. The gradual decrease in height of the nanopatterned structures helps achieve anti reflection and anti-glare properties at the same time.

The present invention is cost effective in comparison to methods known in the art since it does not use organic or dielectric coating, and nor does it use expensive metal/oxide deposition techniques. The material cost for the present invention is approximately 0.3 euro per centimetre square which is considerably much cheaper in comparison to conventional methods.

It will be appreciated that the present invention can be used in a wide range of industrial applications. Photonic devices or optical devices manufactured as per the method disclosed in the present invention can be used in the automotive industry to manufacture for example, vehicle windshields, owing to its antireflective and anti-glare properties. This is also highly advantageous for high volume manufacture of digital devices such as mobile phones, laptops, and devices having a user interface with an optical output. The present invention further finds application in industry segments such as aviation, marine, military, construction, energy, health, optics, textiles, consumer packaging, lipid processing, and advanced electronics.

The present invention hence provides a robust and economic solution to problems identified in the art. Other advantages and additional novel features of the present invention will become apparent from the subsequent detailed description.

In another embodiment there is provided a method for fabricating subwavelength antireflection or antiglare/or scattering Haze nanopatterned structures on one or more surfaces of a substrate, the method comprising the steps of:
depositing a block copolymer material on the one or more surfaces of the substrate; via spin coating or doctor blade or other coating technique;
infiltrating of metal onto one of the polymers, for example using a nickel metal, up to a concentration of approximately 2% or less;
removing a matrix polymer by UV ozone without inverse effect on the metalised etch mask to leave metal on top of the polymer;
fabricating a dense array of nanopatterned structures on the one or more surfaces by a plasma etching process for a pre-determined time duration; and
controlling the dimensions of the nanopatterned structures by optimizing a plurality of etching process parameters, wherein the optimized etching process parameters comprises selective reactive ion etching power, inductively coupled plasma power, and etch gas composition and molar flow rate, and wherein the height of the nanopatterned structures is in the range two hundred to six hundred and fifty nanometers and the aspect ratio of the nanopatterned structures is in the range three to five.

It will be appreciated that high contrast metal/oxide etch mask comprised of any metals and their oxides such as Metal—Ni, Al, Fe, Co, W after selective infiltration to one domains and exposure to UV/Ozone followed by oxygen plasma.

In one embodiment the BCP patterns are made using high molecular weight poly(styrene-b-2-vinylpyridine) (PS₄₄₀-b-P2VP₃₅₃) of around 793 kg mol⁻¹. Clean fused silica substrates from University Wafer type JGS2, double-sided samples with thickness 0.5 mm were spin-coated with 2 wt % PS-b-P2VP in 4:1 toluene:tetrahydrofuran (THF) at 4500 rpm for 30 s. The BCP film was then solvent vapour annealed containing a mixed solvent of 2:1 THF:CHCl₃ for 105 minutes at room temperature and pressure (25 degrees celsius, and ˜1 atm) to cause microphase separation.

In one embodiment the phase separated BCP film is reconstructed to form P2VP islands in a triangular lattice within a PS matrix. The samples were then mixed with an ethanol solvent for 45 minutes at 40° C. to cause swelling of the film. Subsequently, 0.3-0.8 wt % nickel nitrate salt in ethanol was spin-coated (3000 rpm, 30 s) on the swelled film, nickel oxide was incorporated selectively into the P2VP domains. Oxygen plasma was used to remove the matrix polymer and forming a hard mask of nickel oxide dots on the substrate. After pattern transfer on one side, the above process was repeated to pattern the etch mask on the second side of the substrate.

### BRIEF DESCRIPTION OF DRAWINGS

The invention will be more clearly understood from the following description of an embodiment thereof, given by way of example only, with reference to the accompanying drawings, in which:—

FIG. 1 is a flow diagram illustrating a method as per a preferred embodiment of the present invention.

FIG. 2 illustrates block copolymer mask pattern on a glass substrate, as per a preferred embodiment of the present invention.

FIG. 3 is a graphical representation illustrating modelling of height and base diameter of the nanopatterned structures to achieve optimum antireflective properties, as per a preferred embodiment of the present invention.

FIG. 4 is a graphical representation illustrating optical transmission of a plurality of single surface patterned fused silica glass substrates in visible-near infra-red wavelength range, as per a preferred embodiment of the present invention. Also included is an angled SEM showing the height of the nanostructures.

FIG. 5 is a graphical representation illustrating direct optical transmission of a plurality of single surface patterned fused silica glass substrates, as per a preferred embodiment of the present invention.

FIG. 6 is a graphical representation illustrating a comparison of the optical transmission of a plurality of single surface patterned fused silica glass substrates and a plurality of un-patterned glass substrates at various angles of incidence of light.

FIG. 7 is a graphical representation illustrating the optical transmission of curved substrate samples and flat substrate samples at normal incidence of light.

FIG. 8 illustrates the height of nanopatterned structures in various substrate samples achieved by optimising a plurality of etching process parameters, as per a preferred embodiment of the present invention.

FIG. 9 illustrates the height and homogeneity of nanopatterned structures on a large BK7 substrate, as per a preferred embodiment of the present invention. Also shown is the mask prior to etching.

FIG. 10 illustrates phase separation on both sides of a sapphire substrate.

FIG. 11 illustrates the height of the nanopatterned structures fabricated through plasma etching for 20 minutes on the top surface and bottom surface of a substrate, as per a preferred embodiment of the present invention.

FIG. 12 illustrates the height of the nanopatterned structures fabricated through plasma etching for 40 minutes on the top surface and bottom surface of a substrate, as per a preferred embodiment of the present invention.

FIG. 13 illustrates the height of the nanopatterned structures fabricated through plasma etching for 60 minutes on the top surface and bottom surface of a substrate, as per a preferred embodiment of the present invention.

FIG. 14 is a graphical representation illustrating optical transmission of double surface patterned substrate samples in the spectral wavelength range 400-1200 nanometres, as per a preferred embodiment of the present invention.

FIG. 15 is a graphical representation illustrating improved direct transmission on 2-inch diameter double side patterned fused silica at angle of incidence up to 60.

### DETAILED DESCRIPTION OF DRAWINGS

The present invention relates to a method for fabricating nanopatterned substrates, and more particularly to a method for fabricating subwavelength nanopatterned structures on one or more surfaces of a substrate through an optimized anisotropic plasma etching process.

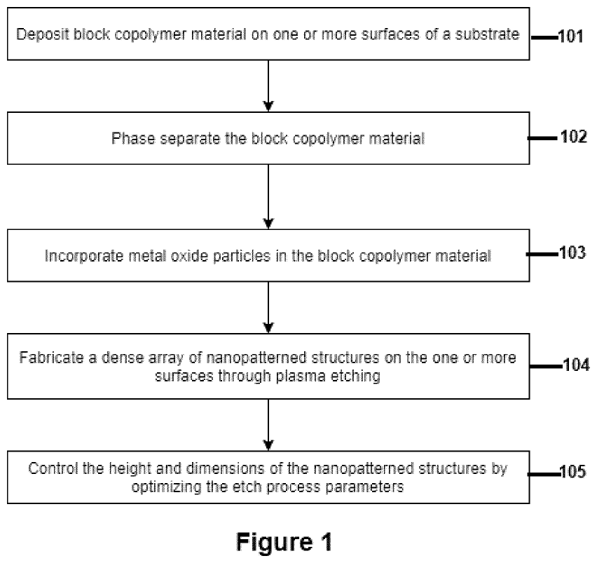

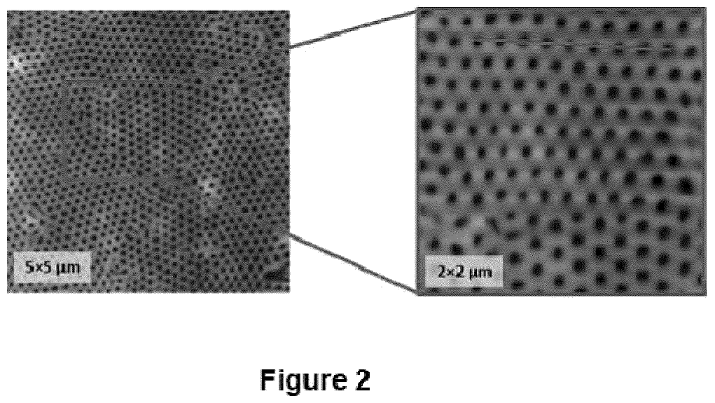

FIG. 1 is a flow diagram illustrating a method as per a preferred embodiment of the present invention. The method comprises the step of depositing a block copolymer (BCP) material on one or more surfaces of the substrate 101. The substrate may be for example a curved substrate or a flat substrate and could be formed of materials such as glass, BK7 glass, gorilla glass, plastic, semiconductor, sapphire, silicon, silicon carbide, or gallium nitride. The deposition of BCP on the substrate is performed by methods such as drop casting, dip coating, or spin coating film. The BCP material is phase separated 102 using one or more solvents selected to facilitate polymer chain mobilization which in turn leads to phase separation. The thickness of the BCP material is in the range of twenty to two hundred nanometres. Further, metal oxide particles are incorporated in the BCP material 103. The surface of the substrate being patterned by an array of dots after BCP templating is illustrated in FIG. 2 which shows a highly ordered mask pattern on glass as per an embodiment of the present invention. The diameter of the dots illustrated in the figure is 100 nanometres and the period, that is the centre to centre distance between the dots, is 170 nanometres.

Thereafter, a matrix polymer is removed by UV ozone, and a masking process is performed that includes creating a metal oxide etch mask by using an oxygen plasma process, to form oxidised metal dots on the FS surface. Thereafter, an etching process is performed that includes fabricating a dense array of nanopatterned structures on the one or more surfaces through a reactive ion plasma etching process for a predetermined time duration 104. Prior to the plasma etching process, optical modelling was performed in order to guide the etch process and determine which pillar dimensions should be targeted in order to achieve anti-glare and antireflective properties. Prior to reactive ion beam etch, the critical oxygen plasma step was performed to reveal the depth of the nanodomain features, and to remove any remaining organic compound.

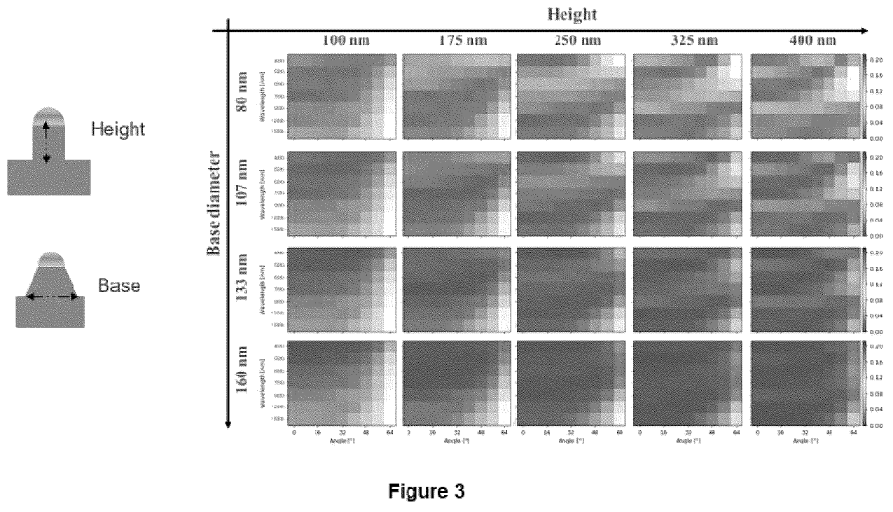

FIG. 3 illustrates modelling of height and base diameter of the nanopatterned structures to achieve optimum anti-reflective properties, as per a preferred embodiment of the present invention. As shown, the appropriate height and base diameter of the nanopatterned structures is modelled for achieving enhanced transmission/antireflectivity over a broad range of spectral wavelength (400 to 1500 nm) at different angles of incidence of light (0-64 degrees).

Based on the results of the optical modelling step, the dimensions of the nanopatterned structures were controlled by optimizing a plurality of etching process parameters 105. Said plurality of etching process parameters comprises Reactive Ion Etching (RIE) power in the range 25-55 watts, Inductively Coupled Plasma (ICP) power in the range 500 to 1000 watts, and oxygen molar flow rate in the range 9 to 21 sccm. Kept constant in all runs was tri-fluoro methane (30 sccm flow rate) and pressure at 15 mTorr. In an embodiment of the present invention the RIE power was 40 watts, the ICP power was 900 watts, the etching gas used was oxygen and tri-fluoro methane, with oxygen being used at a low flow rate of 10 sccm, and the predetermined time duration for the etching process was in the range 20 minutes to sixty minutes and longer for substrates with larger surface area. The plasma etching process is hence optimized by a combination of high RIE power, high ICP power and a ratio of 3:1 tri-fluoro methane:oxygen in the etch gas composition. The dense array of fabricated nanopatterned structures have heights in the range 200 to 650 nanometers and aspect ratio in the range 3-5. The higher aspect ratio leads to enhanced transmittance over a much broader wavelength window. The nanopatterned structures may comprise a dense array of wire shaped or pillar shaped structures or a dense array of substantially conical shaped structures.

In nanotextured surfaces, achieving antireflective and anti-glare property at the same time is challenging as they could require contradictory design requirements. This is achieved by the present invention by densely packing the tapered structures. Tapered profiles enable a smooth transition in refractive index and said profiles were achieved by sidewall engineering using the etch gas composition of oxygen and tri-fluoro methane. The taper profile can be controlled by optimising the plasma conditions such that a fluoro-carbon polymeric product of the tri-fluoro methane plasma is deposited on the sidewalls of the pillars. This passivation layer allows for an anisotropic etch by preventing the exposure of the Si on the sidewalls to the reactive fluorine species present in the plasma. After etching, a second step was performed using oxygen plasma to remove the passivation layer, and clean the surface, exposing the pillars.

The nanostructured surface was simulated using GD-Calc. GD-Calc is based on the rigorous coupled wave approximation (RCWA) and is run in MATLAB. The RCWA is suitable for periodic arrays, typically gratings. The individual pillars were defined as flat-topped (/truncated) cones and were arrange in hexagonal close-packing. The period of the array was kept constant at 160 nm but the height, base diameter and top diameter of the pillars were varied in the ranges 50-500 nm, 80-160 nm and 5-80 nm, respectively. These parameters were chosen to match with structures resulting from PS-b-P2VP patterning.

Using GD-Calc, the reflectance of a fused silica (FS) surface covered with a periodic array of pillars was simulated. The wavelength range considered was 400-1500 nm and the angles of incidence were 0-60°. A flat FS surface reflects ˜3.5% of light in this wavelength range at 0° incidence, increasing to ˜8% at 60°. This will roughly double for a complete substrate (front and back surfaces), so that a FS window reflects ˜7% of light at normal incidence. For each set of height, base diameter and top diameter, the reflectance was recorded and analysed to determine what combinations reduced reflectance the most. It was found that reflectance was reduced over a broad range of wavelengths when (i) the pillars had height >300 nm, (ii) the base diameter was >140 nm and (iii) the top diameter was <30 nm. A surface covered with a perfectly periodic array with these dimensions would have negligible reflectance and glare.

The reflectivity would be ˜0.4-0.65% in the visible spectrum for those dimensions. That is more than 95% improvement in reflection. It's <1% up to a wavelength of 1150 nm.

The ordered array of nanofeatures introduced in our patent allows minimal scattering/haze/glare. When disorder is introduced into an array with these dimensions, scattering of light occurs, resulting in the appearance of haze (/glare).

In reflectance, scattering would happen for wavelengths less than approximately twice the nominal period of the array and would increase as the wavelength decreases.

As the wavelength approaches and decreases below the period of the array, diffractive effects set in. This results in reflections at specific angles. These reflections can be quite large but are only observed at a few discrete angles. The fidelity of range nanostructures allows minimal glare over broadband range of wavelength in UV-Vis and infrared region.

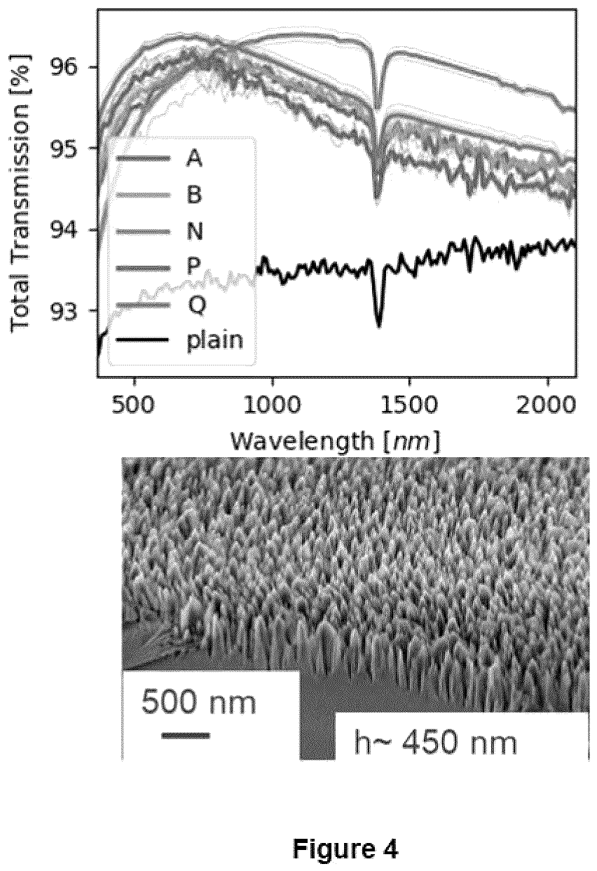

FIG. 4 illustrates the optical transmission of a plurality of single surface patterned fused silica glass substrates in visible-near infra-red wavelength range, as per a preferred embodiment of the present invention. According to theory, a perfect one side treated antireflective fused silica has transmission of approximately 96% in the wavelength range of 380-2000 nm. As shown in FIG. 4, the present invention achieves this in practice. The height of the fabricated nanopatterned structures varies in the range 150 nm to 500 nm.

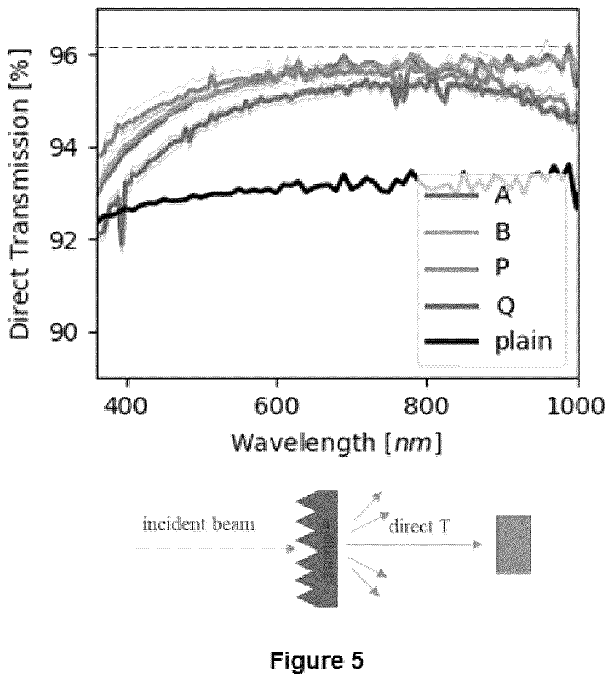

FIG. 5 illustrates direct optical transmission of a plurality of single surface patterned fused silica glass substrates, as per a preferred embodiment of the present invention. The light transmitted along the same direction as the incident beam is measured in this embodiment. As shown, direct transmission is significantly enhanced in single surface patterned fused silica glass substrates, and transmission equivalent to the theoretical limit has been achieved. Further, glare caused by surface scattering due to nano/micro-scale structures is minimized by densely packing the nanoscale structures on the surface in a tapered manner.

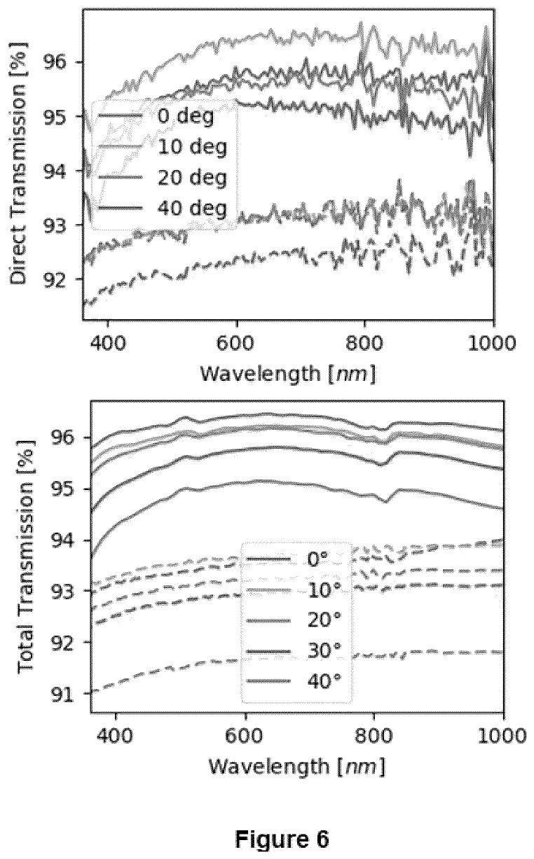

FIG. 6 illustrates a comparison of the optical transmission of a plurality of single surface patterned fused silica glass substrates and a plurality of un-patterned glass substrates at various angles of incidence of light. As shown the transmission of surface patterned glass substrates is significantly higher when compared to that of un-patterned glass substrates. The solid lines represent transmission of patterned substrates at various angles of incidence, and the dotted lines represent transmission of un-patterned substrates at various angles of incidence.

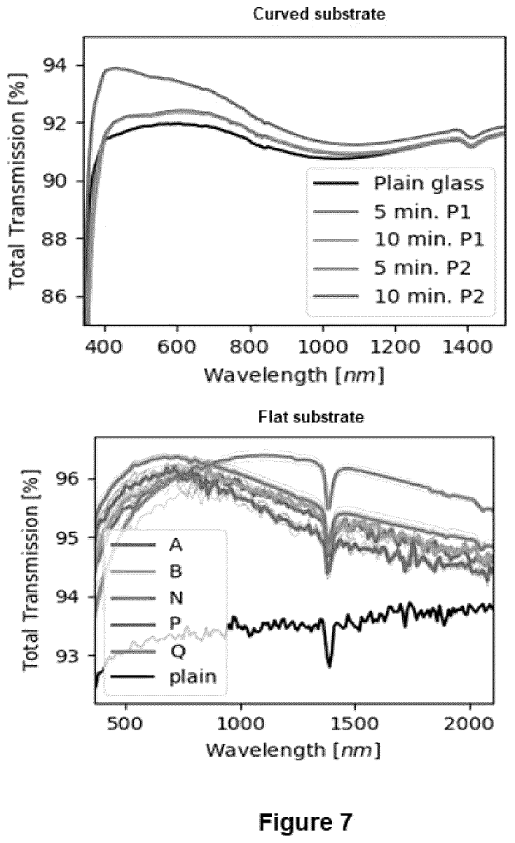

FIG. 7 illustrates the optical transmission of curved gorilla glass substrate samples and flat gorilla glass substrate samples at normal incidence of light. The improvement in transmission for curved surfaces was observed to be lesser compared to that in flat surfaces. This, however, could be attributable to difficulty in etching gorilla glass substrates.

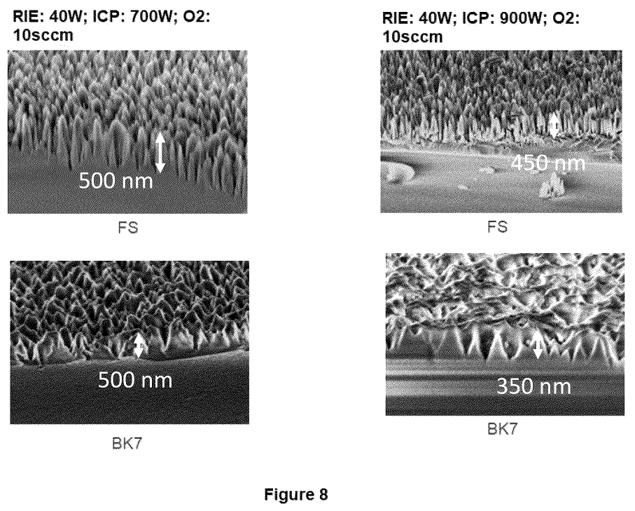

FIG. 8 illustrates the height of nanopatterned structures in various substrate samples achieved by optimising a plurality of etching process parameters, as per a preferred embodiment of the present invention. As shown, a fused silica glass substrate and a BK7 substrate were subjected to anisotropic plasma etching at RIE power: 40 watts, ICP power: 700 watts, and oxygen as one of the etch gases at molar flow rate 10 sccm. A tapered profile of nanostructures with height up to 500 nanometres was observed in the fused silica glass substrate as well as in the BK7 substrate. Further, a fused silica glass substrate and a BK7 substrate were subjected to plasma etching at RIE power: 40 watts; ICP Power: 900 watts; and oxygen as one of the etch gases at molar flow rate 10 sccm. A tapered profile of nanostructures with height up to 450 nanometres was observed in the fused silica glass substrate, and nanostructures with height up to 350 nanometres was observed in the BK7 substrate.

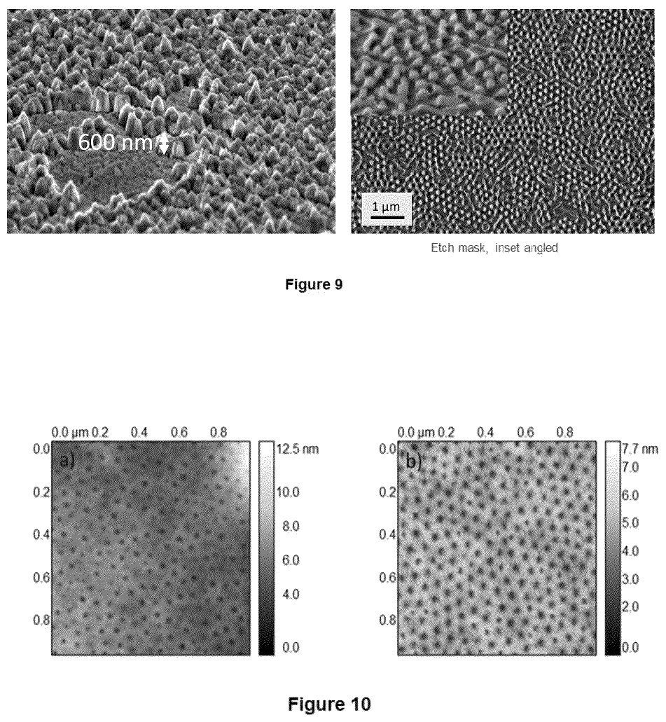

FIG. 9 illustrates the height and homogeneity of nanopatterned structures fabricated by plasma etching for 40 minutes on a large BK7 substrate, as per a preferred embodiment of the present invention. The BK7 wafer used in this embodiment has a diameter of three inches. As shown, the entire substrate is covered by a dense array of nanopatterned structures with maximum heights ranging from 550-650 nanometres. The nanopatterned structures are seen to be homogeneous since the layout of structures at the centre of the sample is similar to that near the edge of the sample. The mask uniformity is also seen to be good with very limited de-wetted area.

FIG. 10 illustrates phase separation of the BCP mask on the top surface and bottom surface of a sapphire substrate. The diameter of the dots was determined as 30 nanometres and the periodicity was determined as 70 nanometres. The soft mask is uniform across both surfaces of the substrate without any de-wetting area.

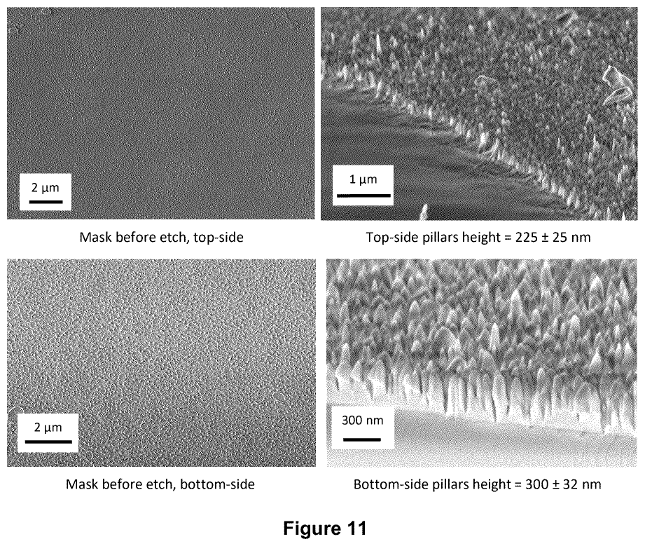

FIG. 11 illustrates the height of the nanopatterned structures fabricated through plasma etching for 20 minutes each on the top surface and bottom surface of a two-inch diameter fused silica glass substrate, as per a preferred embodiment of the present invention. Dense nanopatterned structures of height approximately 225 nanometres were observed to be fabricated on the top surface, and structures of height approximately 300 nanometres were observed to be fabricated on the bottom surface.

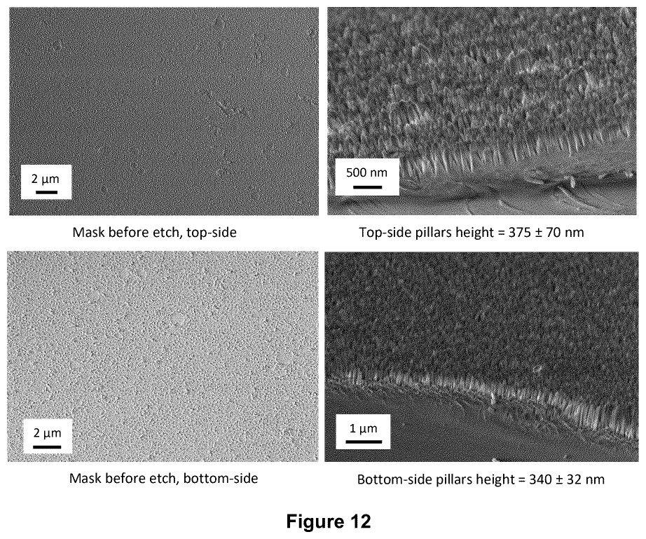

FIG. 12 illustrates the height of the nanopatterned structures fabricated through plasma etching for 40 minutes each on the top surface and bottom surface of a two-inch diameter fused silica glass substrate, as per a preferred embodiment of the present invention. Dense nanopatterned structures of height approximately 375 nanometres were observed to be fabricated on the top surface, and structures of height approximately 340 nanometres were observed to be fabricated on the bottom surface.

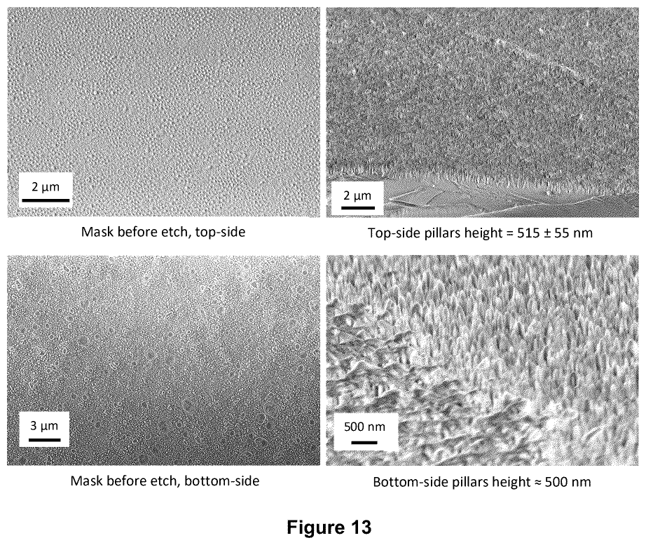

FIG. 13 illustrates the height of the nanopatterned structures fabricated through anisotropic plasma etching for 60 minutes each on the top surface and bottom surface of a two-inch diameter fused silica glass substrate, as per a preferred embodiment of the present invention. Dense nanopatterned structures of height approximately 515 nanometres were observed to be fabricated on the top surface, and structures of height of approximately 500 nanometres were observed to be fabricated on the bottom surface.

The height of the nanopatterned structures on both sides of the substrate can be seen to be increasing with the etch time. Further, the etch rate was observed to decrease as the aspect ratio increased. The height range of 200-550 nanometres is significant to obtain maximum antireflection property at the higher range of visible wavelength. For example, to obtain antireflection properties at wavelength −700 nm, a minimum 350 nm height is required.

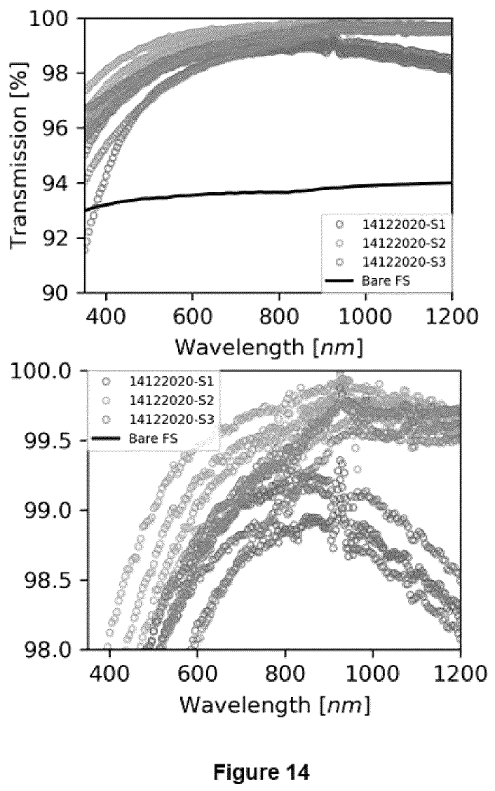

FIG. 14 illustrates the optical transmission of the top surface and bottom surface patterned substrates illustrated in FIGS. 11, 12, and 13, over a wavelength range of 400 to 1200 nanometres. The blue lines represent the transmission of the substrate that was etched for 20 minutes, the orange lines represent the transmission of the substrate that was etched for 40 minutes, and the green lines represent the transmission of the substrate that was etched for 60 minutes. As shown, transmission greater than 99.5% transmission was achieved on the double side nanopatterned and etched samples. This equates to less than 0.5% reflection. Hence, by creating nanostructures with appropriate dimension and morphology to interact with light, the present invention enables an antireflective and anti-glare substrate with near-zero reflection.

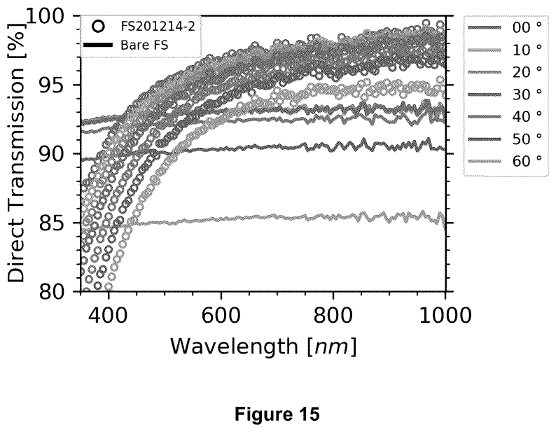

FIG. 15 is a graphical representation illustrating improved direct transmission on a 2 inch diameter double side patterned fused silica at angle of incidence up to 60. The solid lines are for measurements on bare (non-patterned fused silica) and the circle glyphs are measured on double side nanopatterned fused silica.

An indentation test was performed to demonstrate the hardness of a nanopatterned fused silica sample. The indentation test shows that the hardness of the nanopatterned fused silica is comparable to Gorilla glass. It is hence demonstrated that nanopatterning does not adversely affect the mechanical properties such as the hardness of the substrate. The indentation test results are as shown in Table-1 below:

TABLE 1
Indentation Test Results

| Sample Name | Maximum depth (nm) |
|---|---|
| Nanopatterned (D) | 800.4 |
| Non-patterned (2) | 653.5 |
| Gorilla Glass (1) | 631.2 |

The nanopatterned substrates manufactured as per the present invention may be used for a wide range of optical and photonic devices.

In an embodiment of the present invention, the nanopatterned structures and the substrate comprises of the same material, and there is no interface layer or boundary between the nanopatterned structures and the substrate. Although the present invention has been described with reference to specific embodiments, this description is not meant to be construed in a limiting sense. Various modifications of the disclosed embodiments, as well as alternate embodiments of the subject matter, will become apparent to persons skilled in the art upon reference to the description of the subject matter. It is therefore contemplated that such modifications can be made without departing from the spirit or scope of the present invention as defined.

In the specification, the terms “comprise, comprises, comprised and comprising” or any variation thereof and the terms “include, includes, included and including” or any variation thereof are considered to be totally interchangeable, and they should all be afforded the widest possible interpretation and vice versa.

1. A method for fabricating subwavelength antireflection nanopatterned structures on one or more surfaces of a substrate, the method comprising the steps of:
depositing a block copolymer material on the one or more surfaces of the substrate, via spin coating or doctor blade or other coating technique;
incorporating metal oxide particles in the block copolymer material;
removing a matrix polymer by UV ozone;
performing a masking process that includes creating a metal oxide etch mask by using an oxygen plasma process, to form oxidised metal dots on the FS surface;
performing an etching process that includes fabricating a dense array of nanopatterned structures on the one or more surfaces by an induced coupled plasma-reactive ion etching (ICP-RIE) process for a pre-determined time duration; and
controlling the dimensions of the nanopatterned structures by optimizing a plurality of masking and etching process parameters, wherein the optimized masking and etching process parameters comprises selective reactive ion etching power, inductively coupled plasma power, and etch gas composition and molar flow rate, and wherein the height of the nanopatterned structures is in the range two hundred to six hundred and fifty nanometers and the aspect ratio of the nanopatterned structures is in the range three to five.

2. The method as claimed in claim 1, wherein the nanopatterned structures comprises an ordered and dense array of pillar or wire like structures.

3. The method as claimed in claim 1, wherein the nanopatterned structures comprises a dense array of substantially conical shaped structures.

4. The method as claimed in any one of the preceding claims, wherein the reactive ion etching power is in the range twenty-five to eighty watts for the masking process, the inductively coupled plasma power in the range fifty to two hundred watts for the masking process, a feed gas comprises oxygen used at the molar flow rate forty to eighty sccm for the masking process.

5. The method as claimed in anyone of the preceding claims wherein the reactive ion etching power is in the range twenty-five to fifty-five watts for the etching process.

6. The method as claimed in anyone of the preceding claims wherein the inductively coupled plasma power in the range five hundred to one thousand watts for the etching process.

7. The method as claimed in anyone of the preceding claims wherein the etch gas molar flow rate in the range thirty-nine to fifty-one standard cubic centimetres per minute (sccm) for the etching process.

8. The method as claimed in anyone of the preceding claims wherein the etch gas comprises oxygen used at the molar flow rate ten to twenty sccm for the etching process.

9. The method as claimed in anyone of the preceding claims wherein the etch gas comprises tri-fluormethane (CHF₃), used at the molecular flow rate of twenty to thirty one sccm for the etching process.

10. The method as claimed in anyone of the preceding claims wherein the one or more surfaces of the substrate comprises the top surface and bottom surface of the substrate wherein the top surface is disposed opposite to the bottom surface.

11. The method as claimed in anyone of the preceding claims wherein the substrate is a curved substrate.

12. The method as claimed in anyone of the preceding claims wherein the substrate comprises at least one of glass, plastic, semiconductor, sapphire, silicon, silicon carbide, or gallium nitride.

13. The method as claimed in anyone of the preceding claims, wherein the diameter of the substrate is up to six inches or more.

14. The method as claimed in any of the preceding claims, wherein the step of incorporating metal oxide particles in the block copolymer material comprises infiltrating metal onto one of the polymers using a nickel metal, up to a concentration of approximately 2% or less.

15. The method as claimed in anyone of the preceding claims wherein the thickness of the block copolymer material is in the range twenty to two hundred eighty nanometres.

16. The method as claimed in anyone of the preceding claims wherein the predetermined time period is in the range five minutes to sixty minutes.

17. The method as claimed in anyone of the preceding claims wherein the plasma etching process consists of an anisotropic plasma etching process.

18. The method as claimed in anyone of the preceding claims wherein the base diameter of the nanopatterned structures is in the range twenty nanometres to one hundred and sixty nanometres.

19. The method as claimed in anyone of the preceding claims, further comprising the step of phase separating the block copolymer material.

20. A photonic device having a substrate with a dense array of subwavelength nanopatterned structures fabricated according to the method of any of the claims 1-19.

21. An optical device having a substrate with a dense array of subwavelength nanopatterned structures fabricated according to the method of any of the claims 1-19.

22. The device as claimed in anyone of the preceding claims wherein the nanopatterned structures and the substrate comprises of the same material, and wherein there is no interface layer or boundary between the nanopatterned structures and the substrate.

23. The device as claimed in anyone of the preceding claims having an optical transmission greater than 99.5% over spectral wavelength in the range four hundred nanometres to one thousand two hundred nanometres.
